(19) United States
(12) Patent Application Publication
(10) Pub. No.: US 2008/0116496 A1
(43) Pub. Date: May 22, 2008

(54) Integrating a DRAM with an SRAM having butted contacts and resulting devices

(76) Inventors: Kuo-Chyuan Tzeng, Chu-Pei City (TW); Kuo-Chiang Ting, Hsinchu (TW); Chen-Jong Wang, Hsin-Chu (TW); Min-Hsiung Chiang, Banciao (TW); Chih-Yang Pai, Hsinchu City (TW)

Correspondence Address: SLATER & MATSIL, L.L.P., 17950 PRESTON ROAD, SUITE 1000, DALLAS, TX, 75252, US

(21) Appl. No.: 11/809,642

(22) Filed: Jun. 1, 2007

Related U.S. Application Data
(60) Provisional application No. 60/860,258, filed on Nov. 21, 2006.

(51) Int. Cl. H01L 27/108

(52) U.S. Cl. 257/296; 257/E27.084

(57) ABSTRACT

A novel SOC structure and method of making the same are provided. An SOC comprises a logic region, an SRRM and a DRAM region. The storage capacitor in a DRAM cell is formed in the first dielectric layer in an MIM (metal-insulator-metal) configuration, having a large vertical surface area. A butted contact, formed in said first dielectric layer, comprises a bottom portion abutting a first and second conductive region in an SRAM cell, and a vertically aligned top portion coupled to a first metal layer. The top portion has a substantially larger depth than that of the bottom portion, while substantially smaller in size. Forming this SOC structure does not require adding complex, error-prone additional processing steps on an existing CMOS manufacturing process, thus having little impact on the overall SOC product yield.

This application claims the benefit of U.S. Provisional Application No. 60/860,258, filed on Nov. 21, 2006, entitled “Method to Integrate into Embedded DRAM Processes, SRAM Bit Cells With Butted Contacts and Resulting Devices,” which application is incorporated herein by reference.

### TECHNICAL FIELD

The present invention relates generally to integrated circuits containing logic circuits, Static Random Access Memory (SRAM) and Dynamic Random Access Memory (DRAM). More particularly, this invention relates to a method of forming an SOC containing an SRAM and DRAM region, a logic region and an I/O region. This invention also relates to semiconductor devices resulted from said method.

### BACKGROUND

While integrated circuit technology evolves, a system-on-a-chip (SOC) configuration is gaining increasing popularity to provide improved performance for many applications. An SOC improves system performance by integrating multiple functional blocks on a single chip. Embedding large blocks of memory into an SOC enables fast access to a large amount of data with improved data integrity. Such a system configuration also saves die area and consumes much less power, compared with using an external memory module. An SOC with embedded memory is of great benefit to power-stingy applications, such as mobile/portable devices, and multimedia products.

As a reliable, proven technology, an SRAM is the instinctive choice in embedded memory solutions because the manufacturing process of an embedded SRAM is fully compatible with a conventional CMOS fabrication process. Hence, integrating an SRAM on an SOC does not require adding much complexity into an existed CMOS manufacturing process.

FIG. 1 shows a schematic diagram of a conventional six transistor SRAM cell 5. In SRAM cell 5, a first inverter 2, comprising a PMOS transistor P1 and an NMOS transistor N1, is cross-coupled with a second inverter 4, comprising a PMOS transistor P2 and an NMOS transistor N2. The source, drain and gate of each transistor is labeled with an “S,” “D,” or “G,” respectively. The gate electrodes of P1 and N1 and the source regions of P2 and N2 make up a second storage node “A.” The gate electrodes of P2 and N2 and the source regions of P1 and N1 make up a first storage node “B.” The drains of P1 and P2 and the drains of N1 and N2 are coupled to a supply voltage Vdd and ground GND, respectively. During operation, data is written into the SRAM cell 5 by first activating the wordline WL coupled to the access transistor N3 and N4. Subsequently, the digital bit carried on the bitline BL will be passed to the first storage node “B” and the complementary bit on the bitline BL/will be passed to the second storage node “A.” This state will be held until new data is applied on the access transistors N3 and N4.

FIG. 2 shows a schematic diagram of a DRAM cell 10. A digital bit can be stored in a DRAM cell 10 by first activating the wordline WL coupled to the gate electrode of access transistor 20. Subsequently, the value carried on the bitline BL will be passed to and stored in the storage capacitor “C.” A DRAM cell consumes much less power and requires much less die area. These advantageous features have made embedded DRAM a much desirable alternative while the trend of integrating more memory on an SOC continues. However, as known in the art, forming a DRAM cell 10 (more specifically, a storage capacitor) requires adding specialized process steps and new materials. In consequence, an embedded DRAM may be implemented on an SOC only if the added processing cost can be justified for improved system performance. Moreover, in some cases, the additional processing steps can have an adverse effect on other regions of an SOC. Thus, the way the DRAM and standard CMOS processes work together is critically important.

Shown in FIG. 3 is a cross sectional view illustrating a portion of an SOC having a prior art embedded SRAM and DRAM region, a logic region and an I/O region. In the SRAM region, gate electrode “G” of P1 (not shown) is electrically coupled to the source region “S” of P2 through a contact 11, having a much larger size than a regular (square-shaped) contact 12. Contact 11 rides across the gate electrode of P1 and source region of P2, having a configuration generally referred to as a butted contact (BTC). In general, a butted contact 11 has a rectangular shape that is about twice the size of the regular contact 12. Using a butted contact 11 significantly reduces the number of contacts needed in a SRAM cell, thus reducing the die area and enhancing device reliability. In a similar manner, a butted contact (not shown) may be also formed to couple the gate electrode of N2 and the source region of N1 of the SRAM cell shown in FIG. 1. Butted contacts are widely adopted in an embedded SRAM where high memory density is desired.

In the DRAM cell region of FIG. 3, a storage capacitor “C” is formed in a dielectric layer (IDL) between the semiconductor substrate 3 and the first metal layer M1. The capacitor “C” is made in a cup shape to maximize its surface area while taking up the smallest possible die area. The cup is made by forming a first metal cup 15, coating it with a dielectric layer 16, and then forming a second metal cup 17 inside the first two layers. The first metal cup 15 is coupled to the drain region 20d of an access transistor 20 through a regular contact 12. The gate electrode 20g of access transistor 20 is electrically coupled to a wordline (not shown). The source region 20s of access transistor 20 is coupled, through a regular contact 12, to a bitline 25 formed in the first metal layer. The second metal cup 17 of storage capacitor “C” is connected to a plate voltage Vcp (not shown). During operation, data is written into the DRAM cell by activating the wordline coupled to the gate electrode 20g and passing the digital bit on bitline 25 to the storage capacitor “C.” In the prior art, an etch stop layer 13 is generally formed in the IDL to facilitate etching opening for the formation of the storage capacitor “C.”

In order to achieve a good data retention time in the storage capacitor “C,” a largest possible capacitance is desired. While high K (dielectric constant) dielectric materials have been used to form dielectric layer 16, further increase in capacitance depends mainly on the surface area of metal cup 15 and 17. This leads to a very deep storage capacitor “C” being formed in the dielectric layer IDL. As a result, the thickness of the IDL and the depth of a butted contact 11 and a regular contact 12 in this SOC configuration may reach about three to five times of that of an SOC formed by a conventional CMOS process. Forming the aforementioned DRAM storage capacitor and deep contacts in the dielectric layer IDL requires additional processing steps. Moreover, the dry etch process used to form the deep, butted contact 11 and the regular contact 12 may cause significant overall product yield loss.

Firstly, due to the large aspect ratio of contacts in this SOC configuration, cutting contact openings using a dry etch process will take a much longer time than a conventional etch process. Photoresist losses on the edges of the contact openings during the long etch process may become so severe that a known phenomenon called “striation” may occur on the surface region between adjacent contact holes. This phenomenon may cause metal bridging (shorts) between adjacent contacts. As an example, a metal bridging is shown in FIG. 3 between a butted contact 11 and a regular contact 12 on the surface region of the SRAM cell.

Secondly, the etch process used to form contact openings in this SOC configuration is much harder to carry out. In the prior art, the photomask used to pattern the contact openings is tailored for an optimized etch process window for forming contact openings with regular aspect ratio. The etch process window will become significantly smaller when conducting a similar etch process to form contact openings with a much larger aspect ratio. Although a new photomask can be developed in correspondence with a new OPC (optical proximity correction) model, taking into account the deep contact openings. Developing such a model is, however, a separate challenge, because the model involves not only an extraordinarily deep etching profile, but also contacts of various shapes (square and butted). Logical operation employed to create the model must conduct complex calculation that is time-consuming and costly. Finally, the negative effects mentioned above will deteriorate with each new technology generation.

In view of these and other problems in the prior efforts to integrate a DRAM into an existing CMOS manufacturing process, there is a need for an improved or new SOC structure and method of forming the same, where the integration of a DRAM would not involve adding complex, error-prone processing steps, thus having little impact on the overall SOC product yield.

### SUMMARY OF THE INVENTION

These and other problems are generally solved or circumvented, and technical advantages are generally achieved, by preferred embodiments of the present invention which provide an SOC structure where a butted contact in an SRAM cell region comprises a large size bottom portion and a small size top portion. The top portion is formed to make an electrical connection to the first metal layer, while the bottom portion is formed to make a local connection to two conductive regions in a semiconductor substrate. The top portion is substantially deeper than the bottom portion. Forming an SOC using this butted contact structure can avoid creating a high aspect ratio, and large size butted contact openings through the first dielectric layer. This advantageous feature enables forming a deep DRAM storage capacitor in the first dielectric layer without affecting the yield of an SRAM cell.

In accordance with a preferred embodiment of the present invention, a semiconductor device comprises a semiconductor substrate having a first, a second, and a third conductive region, a dielectric layer formed atop said substrate, a first and a second conductive feature formed atop the surface of said dielectric layer, a first contact formed in said dielectric layer coupling said first conductive region to said first conductive feature, a second contact formed in said dielectric layer comprising a bottom portion abutting said second and third conductive region and a top portion coupled to said second conductive feature, wherein the size of said bottom portion is substantially larger than that of said top portion.

In accordance with another preferred embodiment of the present invention, a semiconductor device comprises a semiconductor substrate having a first, a second, and a third conductive region, a first dielectric layer formed atop said substrate, a second dielectric layer substantially thicker formed atop said first dielectric layer, a first and a second conductive feature formed atop the surface of said second dielectric layer, a first contact formed in said first and second dielectric layer coupling said first conductive region to said first conductive feature, a second contact formed in said first dielectric layer coupled to said second and third conductive region, a third contact formed in said second dielectric layer, wherein said third contact overlaps said second contact coupling said second contact to said second conductive feature, and the size of said second contact is substantially larger than that of said third contact.

In accordance with yet another preferred embodiment of the present invention, a semiconductor device comprises a semiconductor substrate having a logic region, and an SRAM cell region, a dielectric layer formed atop said substrate, a first and a second conductive feature formed atop the surface of said dielectric layer, a first MOS transistor formed in said logic region, comprising a first conductive region, a second MOS transistor formed in said SRAM region, comprising a second and third conductive region, a first contact formed in said dielectric layer coupling said first conductive region to said first conductive feature, a second contact formed in said dielectric layer comprising a bottom portion abutting said second and third conductive region and a top portion coupled to said second conductive feature, wherein the size of said bottom portion is substantially larger than that of said top portion.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic view of a prior art SRAM cell;

FIG. 2 is a schematic view of a prior art DRAM cell;

FIG. 3 shows a cross sectional view of a prior art SOC contact structure; and

FIGS. 4-6 show the cross sectional views of a preferred embodiment SOC contact structure through various processing steps.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

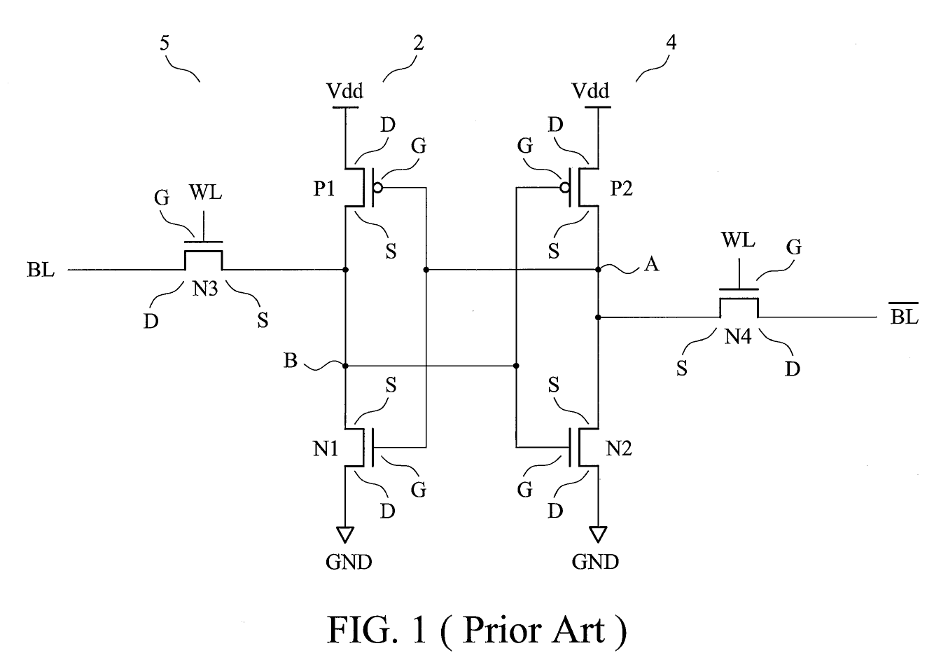

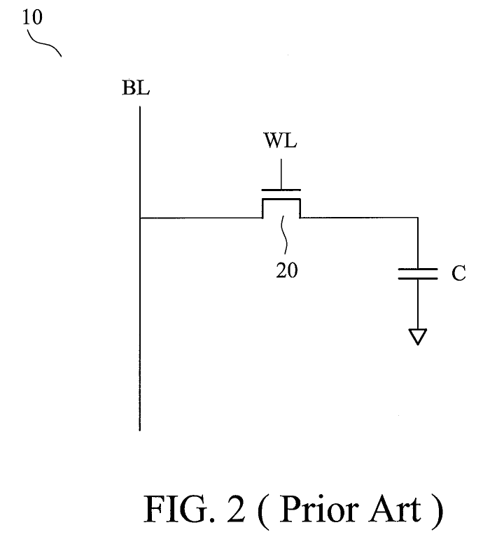

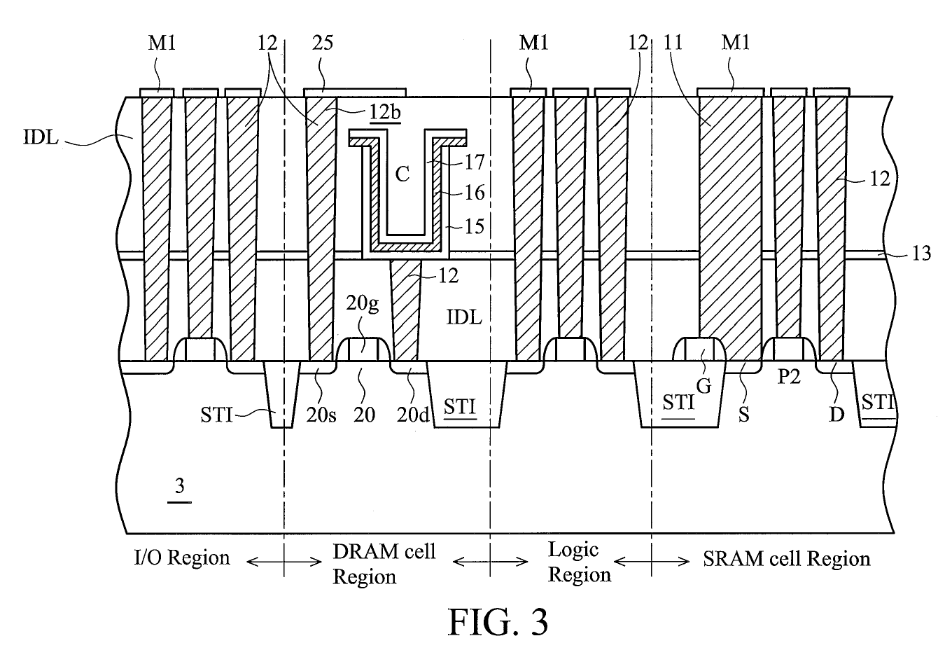

The present invention will be described with respect to preferred embodiments in a specific context, namely an improved SOC structure and the method of forming the same. This inventive SOC structure comprises an SRAM and DRAM region, a logical region, and an I/O region. The integration of a DRAM region does not involve adding complex, error-prone processing steps. The additional process steps will have little impact on the overall SOC product yield. To clarify description and avoid repetition, like numerals and letters used to describe the prior art in FIGS. 1-3 will be used for the various elements in the coming figures. Also, reference numbers described in FIGS. 1-3 may not be described again in detail herein.

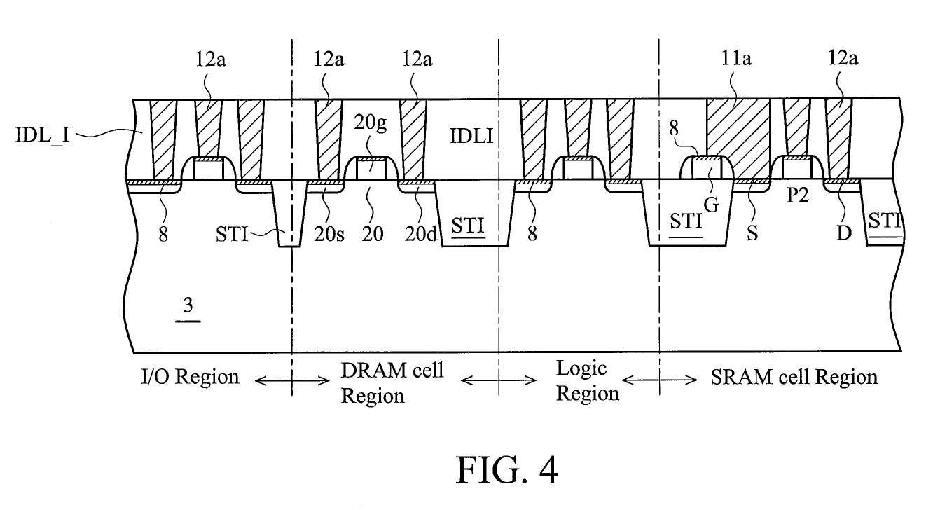

Starting with FIG. 4, a semiconductor substrate 3 is provided. In a preferred embodiment, the semiconductor substrate 3 is a silicon substrate with a desired doping concentration. In other embodiments, semiconductor substrate 3 may be a silicon germanium, gallium arsenide, compound semiconductor, multi-layers semiconductor, silicon on insulator (SOI), germanium on insulator (GeOI), and the like. On the semiconductor substrate 3, an SRAM region, a logic region, a DRAM region, and an I/O region are defined. Semiconductor devices, such as the NMOS access transistor 20 in a DRAM cell and the PMOS transistor P2 in an SRAM cell, have been formed in the desired regions on the semiconductor substrate 3 by known materials and processes. In preferred embodiments, an optional silicide layer 8 may be formed atop the gate electrode and source/drain regions of a MOS device by a silicide process, in order to reduce the resistance of the gate electrode and diffusion regions. The silicide is preferably NiSi₂, CoSi₂, TiSi₂ or the like. The Shallow Trench Isolations (STI) are formed in the semiconductor substrate 3 to isolate adjacent devices. Preferably, the STIs are formed by etching shallow trenches in the semiconductor substrate 3, and filling the trenches with an insulator such as silicon oxide formed by HDPCVD (high-density plasma chemical vapor deposition) or SACVD (sub-atmospheric chemical vapor deposition) method. From hereafter, “semiconductor substrate” is used to refer to the starting semiconductor substrate 3, while “substrate” is used to refer to a finished wafer surface after an intermediate process step in a preferred embodiment.

A first dielectric layer IDL_I is formed atop the semiconductor substrate 3. In a preferred embodiment, IDL_I is a CVD silicon oxide layer with a regular dielectric constant value. In another embodiment, IDL_I is carbon-doped silicon oxide layer or Fluorine-doped Silicate Glass (FSG) having a dielectric constant smaller than 3.5, although other low k materials comprising C, O, H are not excluded. In preferred embodiments, IDL_I has a thickness of from about 2000 Å to about 5000 Å. Other suitable dielectric materials and processes of forming IDL_I are not excluded. A photomask MSK_1 defining the electrical connections (contacts) to the semiconductor devices previously formed in semiconductor substrate 3 is developed. The OPC (optical proximity correction) model of MSK_1 is developed, taking into account factors such as contact shapes, etch depth, photoresist thickness, and the like. A known photolithography process may be used to transfer the contact pattern to the IDL_I layer on the semiconductor substrate 3. A known etch process, such as an anisotropic dry etch process can be performed after the lithography to remove unwanted IDL_I material and form contact openings in IDL_I. These contact openings may include square-shaped openings 12a, exposing a conductive region on a semiconductor device, such as a gate electrode 20g, a source region 20s, or a drain region 20d of a MOS access transistor 20 in the DRAM region. A square shaped contact opening 12a has a minimum contact opening size allowed by the design rule. The contact openings may also include rectangular-shaped openings (e.g., two butted square shaped contact openings), such as 11a formed in an SRAM cell region, exposing the gate electrode “G” of one MOS transistor P1 (not shown) and the source region “S” of another MOS transistor P2. A rectangular shaped contact opening 11a has at least about 1.5 times the minimum contact opening size allowed by the design rule, preferably from about 1.5 to 2.5 times the minimum contact opening size allowed by the design rule. In order to achieve a maximum possible device density formed on an SOC, the space between adjacent contact openings has a minimum contact-to-contact spacing allowed by the design rule. Afterward, a contact such as a tungsten plug may be formed in all the contact openings by a known process, such as a blanket CVD tungsten deposition on the substrate surface or a selective CVD tungsten growth in the contact openings. In preferred embodiments, a TiN (titanium nitride) layer (not show) may be formed by a known process on the bottom of the contact openings, prior to the formation of a tungsten plug. A TiN layer thus formed acts as a barrier layer to prevent detrimental effects, such as electromigration. Other suitable conductive materials or processes may also be used to form a contact. A regular contact formed in a square shaped contact opening 12a provides electrical connection to a conductive region on the semiconductor substrate 3, such as a gate electrode, a source region, or a drain region of a MOS transistor. A butted contact formed in a rectangular shaped contact opening 11a couples locally one conductive region to another on the semiconductor substrate 3. These contacts are generally referred to as CONT1 hereafter. Then, a known planarization process such as a chemical mechanical polishing (CMP) process is applied on the substrate surface to remove the excess tungsten formation over the tungsten plugs and tungsten particles formed on the substrate surface, providing a substantially flat substrate surface preferable for the subsequent processing steps.

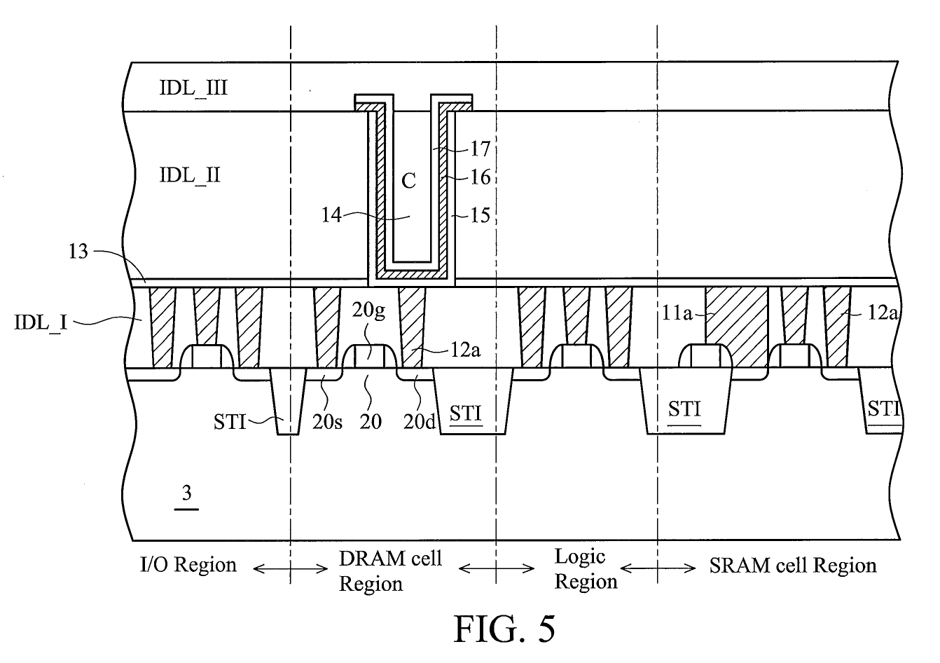

Continuing in FIG. 5, an etch stop layer 13 made preferably of silicon nitride (Si₃N₄) or silicon oxynitride (SiON) is formed atop the substrate by a known process. A second dielectric layer IDL_II is formed atop the etch stop layer 13. In a preferred embodiment, IDL_II is made of the same dielectric material used in forming the first dielectric layer IDL_I, through a similar known deposition process. IDL_II formed by other suitable dielectric materials and processes are not excluded. In preferred embodiments, IDL_II has a thickness of from about 5000 Å to about 20000 Å. Afterward, a known photolithography and etch process are employed to form openings 14 in the second dielectric layer IDL_II, where a DRAM storage capacitor “C” in an MIM (metal-insulator-metal) configuration is formed. The storage capacitor “C” is made in a cup shape to maximize its surface area while taking up the smallest possible die area. In doing so, a first metal layer is formed on the substrate and patterned to form a first metal cup 15, by known deposition, photolithography and etch processes. Suitable materials for the first metal cup 15 may include elemental metal, metal composite, metal alloy or any combination in a single or a multi-layer configuration. After the current process step, the first metal cup 15 is coupled to the drain region 20d of an access transistor 20 through a regular contact 12a. Next, a layer of high K (dielectric constant) material, such as Al₂O₃, Ta₂O₅, HfO, ZrO₂, is coated on the substrate to form the dielectric layer 16 of storage capacitor “C.” Preferably, the dielectric layer 16 is formed with a smallest possible thickness in order to provide desired large capacitance between the capacitor plates. Subsequently, a second metal layer is formed on the substrate and patterned to form a second metal cup 17. The conductive materials and processes used to form the second metal cup 17 is the same as those used to form the first metal cup 15, although different conductive materials and processes are not excluded. Finally, a third dielectric layer IDL_III is formed atop the substrate to isolate adjacent storage capacitors from one another. In a preferred embodiment, the layer IDL_III is formed by the same material and process used in forming the second dielectric layer IDL_II and the first dielectric layer IDL_I, having a thickness of from about 500 Å to about 3000 Å.

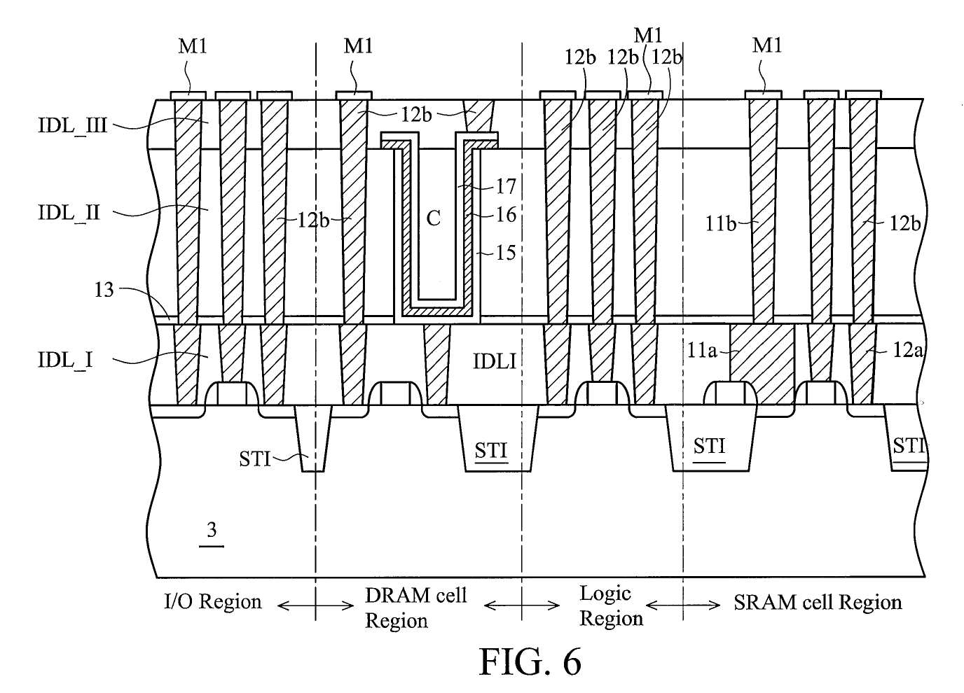

Turning now to FIG. 6, after the formation of the storage capacitor “C,” another photolithography process may be used to transfer a second contact pattern to the surface of the IDL_III layer on the substrate. The second contact pattern serves the purpose of creating contact openings in the second and the third dielectric layers and forming electrical connections to the earlier formed CONT1 in the first dielectric layer. To simplify description, contacts formed in IDL_II and IDL_III are generally referred to as CONT2 hereafter. Ideally, CONT2 needs to be well aligned with CONT1, stacking atop the surface of CONT1, in order to save die area and avoid shorting at the IDL_I and IDL_II interface. In the preferred embodiments, the photomask defining the CONT2 pattern is developed by adopting the previous OPC (optical proximity correction) model used in forming CONT1, while swapping the pattern of the butted contact 11a in the previous OPC model with the pattern of a regular contact 11b. This approach provides several advantageous features. First, the development of the current OPC model is greatly simplified, because the current OPC model involves only minor changes from the previous OPC model. Thus the time, effort and cost of developing the photomask can be significantly reduced. Second, a regular contact 11b thus formed stacking atop the surface of a butted contact 11a in an SRAM cell region can significantly lower the risk of potential SRAM cell yield loss. In one sense, the potential photo loss caused bridging on the substrate surface between a butted contact a regular contact can be reduced or even avoided, since the space between a regular contact 11b and an adjacent regular contact 12b is larger than the minimum design rule contact spacing. Surface “striation” between 11b and 12b is less likely to occur during an etch process, due to the increased process margin. In another sense, the potential risk of shorting between contact 11b and 12a at the IDL_I and IDL_II interface can be reduced or avoided, because the current CONT2 configuration in the SRAM cell region is more tolerant to a misalignment between CONT1 and CONT2 occurred during a lithography process. Third, an etch process window can be significantly enlarged due to the fact that a current etch recipe needs only to be tailored to cover the large aspect ratio of CONT2, with little concern on creating etch profiles of different contact shapes. As a result, an etch recipe for forming a deeper storage capacitor becomes much easier to achieve. These and other advantageous features of the preferred embodiments can be readily appreciated by those skilled in the art.

A known photolithography process may be used to transfer the pattern of CONT2 onto the substrate. A known etch process, such as an anisotropic dry etch process can be performed after the lithography to remove unwanted IDL_II and IDL_III materials and form contact openings therein. A known contact formation process such as a tungsten plug by blanket CVD tungsten deposition or selective CVD tungsten growth can be employed to fill the contact openings. Other suitable contact metals, such as aluminum or copper and known processes of forming can also be used. In the preferred embodiments, a TiN layer (not show) may be formed by a known process on the bottom of the CONT2, prior to the formation of a tungsten plug, in order to avoid detrimental effects, such as electromigration. A known planarization process such as a chemical mechanical polishing (CMP) process is applied on the substrate surface to remove the excess tungsten formation over the contacts and tungsten particles formed on the substrate surface, providing a substantially flat substrate surface preferable for the subsequent processing steps. After the formation of CONT2, the second metal cup 17 of a storage capacitor “C” in a DRAM cell may be electrically coupled to a plate voltage Vcp (not shown) through a regular contact 12b. Lastly, a metal layer is deposited on the substrate and patterned by a known deposition, photolithography, etch, and planarization process to form the first conductive layer M1 in an SOC. The finished SOC structure is shown in FIG. 6.

Although the present invention and its advantages have been described in detail, it should be understood that various changes, substitutions and alterations can be made herein without departing from the spirit and scope of the invention as defined by the appended claims. For example, in another embodiment, IDL_I has only a thickness of from about 800 Å to about 1500 Å, while IDL_II has a thickness of from about 7500 Å to about 19000 Å. This SOC configuration provides an even larger metal cup surface area for a DRAM storage capacitor, thus further improving the performance of a DRAM cell. In yet another embodiment, CONT2 and M1 can be formed through a known copper dual damascene process, thus reducing process cost and enabling more conductive layers in an SOC. In a further embodiment, CON2 and M1 can be formed by a single damascene process, respectively. As another example, it will be readily understood by those skilled in the art that materials, process steps, process parameters in forming the preferred embodiments may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor substrate having a first, a second, and a third conductive region;
a dielectric layer formed atop said substrate;
a first and a second conductive features formed atop the surface of said dielectric layer;
a first contact formed in said dielectric layer coupling said first conductive region to said first conductive feature;
a second contact formed in said dielectric layer comprising a bottom portion abutting said second and third conductive region and a top portion coupled to said second conductive feature;
wherein the size of said bottom portion is substantially larger than that of said top portion.

2. The device of claim 1, wherein said conductive region is the gate region, the source region, or the drain region of a MOS transistor.

3. The device of claim 1, wherein said dielectric layer is a low K (dielectric constant) dielectric material having a dielectric constant less than about 3.5.

4. The device of claim 1, wherein said first and second contact comprises a tungsten plug.

5. The device of claim 1, wherein said top portion of said second contact is at least two times deeper than said bottom portion.

6. The device of claim 1, wherein said second conductive feature is formed by a single damascene process.

7. The device of claim 1, wherein said top portion of said second contact and said second conductive feature is formed through a copper dual damascene process.

8. A semiconductor device comprising:
a semiconductor substrate having a first, a second, and a third conductive region;
a first dielectric layer formed atop said substrate;
a second dielectric layer substantially thicker formed atop said first dielectric layer;
a first and a second conductive feature formed atop the surface of said second dielectric layer;
a first contact formed in said first and second dielectric layer coupling said first conductive region to said first conductive feature;
a second contact formed in said first dielectric layer abutting said second and third conductive region;
a third contact formed in said second dielectric layer;
wherein said third contact overlaps said second contact coupling said second contact to said second conductive feature, and the size of said second contact is substantially larger than that of said third contact.

9. The device of claim 8 wherein said device further comprises a MIM (metal-insulator-metal) capacitor formed in said second dielectric layer.

10. The device of claim 8 wherein said first and second conductive feature is a copper wire formed in the first metal layer.

11. The device of claim 8 wherein said device further comprises a logic region and an SRAM cell region, said first contact is in said logic region, and said second and third contact is in said SRAM region.

12. The device of claim 8 wherein said device further comprises a logic region and an SRAM cell region, said second and third conductive region is the gate region of one MOS transistor and the source/drain region of another MOS transistor in said SRAM cell region.

13. A semiconductor device comprising:
a semiconductor substrate having a logic region, and an SRAM cell region;
a dielectric layer formed atop said substrate;
a first and a second conductive feature formed atop the surface of said dielectric layer;
a first MOS transistor formed in said logic region, comprising a first conductive region;
a second MOS transistor formed in said SRAM region, comprising a second and third conductive region;
a first contact formed in said dielectric layer coupling said first conductive region to said first conductive feature;
a second contact formed in said dielectric layer comprising a bottom portion abutting said second and third conductive region and a top portion coupled to said second conductive feature;
wherein the size of said bottom portion is substantially larger than that of said top portion.

14. The device of claim 13 wherein said device further comprises a DRAM cell region 15.

15. The device of claim 14 wherein the storage capacitor of said DRAM cell region is an MIM (metal-insulator-metal) capacitor formed in said second dielectric layer.

16. The device of claim 13 wherein said second conductive region is the gate region of one MOS transistor and said third conductive region is the source/drain region of another MOS transistor in said SRAM cell region.

17. The device of claim 13, wherein said top portion of said second contact is at least two times deeper than said bottom portion.

18. The device of claim 13, wherein the size of said bottom portion is at least about 1.5 times larger than said top portion.

19. The device of claim 13, wherein said top portion of said second contact and said second conductive feature is formed through a copper dual damascene process.

20. The device of claim 13, wherein said second conductive feature is formed by a single damascene process.
